(19) United States
(12) Patent Application Publication
(10) Pub. No.: US 2026/0096212 A1
(43) Pub. Date: Apr. 2, 2026

(54) ELECTRONIC DEVICE

(71) Applicant: InnoLux Corporation, Miao-Li County (TW)

(72) Inventors: Yung-Shun YANG, Miao-Li County (TW); Fu-Min WANG, Miao-Li County (TW); Sheng-Feng HUANG, Miao-Li County (TW); Yu-Mei CHIU, Miao-Li County (TW)

(21) Appl. No.: 19/286,429

(22) Filed: Jul. 31, 2025

(30) Foreign Application Priority Data
Sep. 30, 2024 (CN) 202411378219.5

(51) Int. Cl. H10D 86/40; H10B 12/00; H10N 39/00

(52) U.S. Cl. CPC H10D 86/431; H10B 12/30; H10B 12/50; H10N 39/00

(57) ABSTRACT

An electronic device includes: a substrate; a first transistor disposed on the substrate and having a first operating voltage; and a second transistor disposed on the substrate and having a second operating voltage. The first transistor includes a first semiconductor layer, a first gate, and a first insulating structure. The first insulating structure is disposed between the first semiconductor layer and the first gate. The second transistor includes a second semiconductor layer, a second gate, and a second insulating structure. The second insulating structure is disposed between the second semiconductor layer and the second gate. The first operating voltage is higher than the second operating voltage, and a thickness of the first insulating structure is greater than a thickness of the second insulating structure.

### CROSS REFERENCE TO RELATED APPLICATIONS

This application claims priority of China Patent Application No. 202411378219.5, filed Sep. 30, 2024, the entirety of which is incorporated by reference herein.

### TECHNICAL FIELD

The present disclosure relates to an electronic device, and in particular, to an electronic device simultaneous configuring a high-voltage electronic element and a low-voltage electronic element.

### BACKGROUND

Electronic devices have been broadly applied in the fields of communication, display, automobiles, aviation, and the like. As the development of electronic devices continues to advance, research into electronic devices has been focused on producing lighter and thinner products. Therefore, demand has increased for electronic devices with better reliability and higher quality.

Although electronic devices have been generally adequate for their intended purposes, they have not been entirely satisfactory in all respects. For example, conventional thin film transistors (TFT) are generally driven by low voltages. As the thin film transistors have become more broadly applied (for example, in the fields of medicine, communication, or the like), the possibility of manufacturing an electronic device simultaneously having a high-voltage electronic element and a low-voltage electronic element is thus necessary.

### BRIEF SUMMARY

An embodiment of the present disclosure provides an electronic device, the electronic device includes: a substrate; a first transistor disposed on the substrate and having a first operating voltage; and a second transistor disposed on the substrate and having a second operating voltage. The first transistor includes a first semiconductor layer, a first gate, and a first insulating structure, the first insulating structure is disposed between the first semiconductor layer and the first gate. The second transistor includes a second semiconductor layer, a second gate, and a second insulating structure, the second insulating structure is disposed between the second semiconductor layer and the second gate. The first operating voltage is higher than the second operating voltage, and a thickness of the first insulating structure is greater than a thickness of the second insulating structure.

Another embodiment of the present disclosure provides an electronic device, the electronic device includes: a substrate; a first transistor disposed on the substrate and having a first operating voltage; and a second transistor disposed on the substrate and having a second operating voltage. The first transistor includes a first semiconductor layer, a first gate, and a first insulating structure, the first insulating structure is disposed between the first semiconductor layer and the first gate. The first semiconductor layer includes a first channel region, a first lightly doped region, and a first heavily doped region. The second transistor includes a second semiconductor layer, a second gate, and a second insulating structure, the second insulating structure is disposed between the second semiconductor layer and the second gate. The second semiconductor layer includes a second channel region, a second lightly doped region, and a second heavily doped region. The first operating voltage is higher than the second operating voltage, and a length of the first lightly doped region is greater than a length of the second lightly doped region.

### BRIEF DESCRIPTION OF THE DRAWINGS

The present disclosure can be more fully understood by reading the subsequent detailed description and examples with references made to the accompanying drawings, wherein:

FIGS. 1-6 are various cross-sectional views of intermediate stages of an electronic device, according to some embodiments of the present disclosure;

FIG. 7 is a top view of the electronic device, according to some embodiments of the present disclosure;

FIGS. 8 and 9 are various cross-sectional views of intermediate stages of an electronic device, according to some embodiments of the present disclosure; and

FIGS. 10 and 11 are various cross-sectional views of intermediate stages of an electronic device, according to some embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity, and does not in itself dictate a relationship between various embodiments and/or configurations discussed.

The direction-related terms mentioned in the context, such as “up,” “down,” “front,” “back,” “left,” “right,” and the like, merely refers to the relative direction in the figures. Therefore, the direction-related terms are for illustration, and they are not intended to limit the present disclosure.

Furthermore, in some embodiments of the present disclosure, terms that describe a joining or connecting action, such as “connect”, “interconnect”, or the like, unless otherwise defined, may include embodiments in which two features are formed in direct contact, and they may also include embodiments in which additional features may be formed between the two features. Regarding the terms, such as “connect”, “interconnect”, or the like, may also include embodiments in which the two features are both mobile, or the two features are both fixed. Furthermore, terms, such as “electrically connected”, “coupled”, or the like, may include any means to directly or indirectly establish electrical connection.

In addition, terms, such as “the first”, “the second”, or the like, mentioned in the specification or the claims are only used to name different elements or to distinguish different embodiments or examples, and they are not intended to limit the upper limit or the lower limit of the element quantity, and they are also not intended to limit the manufacturing order or the placement order of the elements.

In the present disclosure, the terms “about,” “approximately” and “substantially” typically mean ±20% of the stated value, more typically ±10% of the stated value, more typically ±5% of the stated value, more typically ±3% of the stated value, more typically ±2% of the stated value, more typically ±1% of the stated value, and even more typically ±0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which the present disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

Some variations of the embodiment are described. In different figures and illustrated embodiments, like reference numerals and/or letters are used to label like elements. It should be appreciated that additional operations can be provided before, during, and/or after the methods described in these embodiments. Additional features can be added to the semiconductor device structure. Some of the operations described below can be replaced or eliminated for different embodiments of the methods.

Throughout the context, each direction is not limited to perpendicular coordinates (such as X-axis, Y-axis, and Z-axis), and may be interpreted in a broader scope. For example, X-axis, Y-axis, and Z-axis may be perpendicular with each other, or they can represent different directions that are not perpendicular with each other. For ease of illustration, in the following context, X-axis is a lengthwise direction, Y-axis is a widthwise direction, and Z-axis is a thickness direction. In the embodiments of the present disclosure, Z-axis is a normal direction of the substrate plane. In the embodiments of the present disclosure, top views refer to the observation of the x-y plane. In some embodiments, the first direction D1, the second direction D2, and the third direction D3 may be directions on the x-y plane. In some embodiments, the dimensions in different directions may be measured using optical images (for example, an image obtained by a scanning electron microscope (SEM)).

In the embodiments of the present disclosure, electronic devices may include a display apparatus, a backlight apparatus, an antenna apparatus, a sensor apparatus, or a stitching apparatus, but the present disclosure is not limited thereto. The electronic devices may be a bent or a flexed device. The display apparatus may be a non-self light emitted type display device or a self light emitted type display device. The antenna apparatus may be a liquid-crystal state device or a non-liquid-crystal state antenna device. The sensor apparatus may be a sensor device that senses capacitance, light rays, heat energy, or supersonic wave, but the present disclosure is not limited thereto. The electronic devices may include passive components or active components, for example, capacitors, resistors, inductors, diodes, transistors, or the like. The diodes may include a light emitting diode (LED) or a photodiode (PD). The light emitting diode may include for example an organic light emitting diode (OLED), a mini light emitting diode, a micro light emitting diode (μLED), or a quantum dot light emitting diode, but the present disclosure is not limited thereto. The stitching apparatus may be a display stitching device or an antenna stitching device, but the present disclosure is not limited thereto. It should be noted that the electronic devices may be any combinations of the aforementioned devices, but the present disclosure is not limited thereto. The following context may use the display apparatus or the stitching apparatus as the electronic devices to describe the subject matter of the present disclosure, but the present disclosure is not limited thereto.

Furthermore, the appearance of the electronic devices may be rectangular-shape, circular-shape, polygon-shape, curved edges-shape, or the like. The electronic devices may have a processing system, a driving system, a control system, a light source system, a shelf system, and other peripheral systems to support the display apparatus or the stitching apparatus. It should be noted that the electronic devices may be any combinations of the aforementioned systems, but the present disclosure is not limited thereto.

Conventional electronic devices (such as low temperature polysilicon (LTPS) thin film transistors) are mainly driven by low voltages (for example, lower than 20V). As the low temperature polysilicon thin film transistors begin to be applied in the medical field, some products require to be driven by high voltages (for example, higher than 50V). However, the process of the high-voltage element and the process of the low-voltage element varied significantly. For example, the high-voltage element is unable to adopt the process conditions of the low-voltage element, since the stress from the high-voltage operation may deteriorate the low-voltage element. On the other hand, if the low-voltage element were to adopt the process conditions of the high-voltage element, the device characteristics may degrade, for example, an increase in threshold voltage variation or a decrease in on-state current. When the gate voltage is too high, it may result in a vertical stress on the device, also known as the bias temperature stress (BTS). When the drain voltage is too high, it may result in a horizontal stress on the device, also known as the channel hot carrier (CHC) stress. Both stresses may lead to device damage and characteristics failure.

The electronic device of the present disclosure integrates the high-voltage element and the low-voltage element on the same substrate. The inventor has discovered that the high-voltage element and the low-voltage element may be operated simultaneously through adjusting the thickness of the gate insulating structure, as well as the length and the concentration of the lightly doped region of the high-voltage element. Specifically, a strong electric field may be generated during the operation of the high-voltage element. In the high-voltage element, the horizontal electric field may be reduced by increasing the length and decreasing the concentration of the lightly doped region. Furthermore, the vertical electric field may be reduced by increasing the thickness of the gate insulating structure in the high-voltage element. The high-voltage element and the low-voltage element may be fabricated on the same substrate through an innovative process design, where the high-voltage element has a thicker gate insulating structure, as well as a longer lightly doped region with lower concentration, in comparison with the low-voltage element.

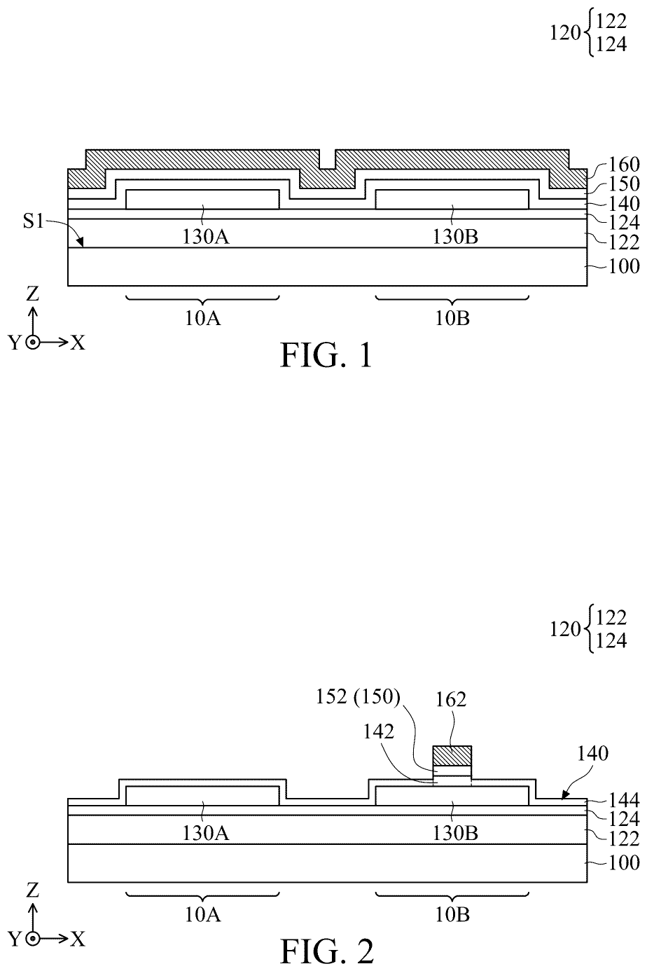

FIGS. 1-6 are various cross-sectional views of intermediate stages of an electronic device 10, according to some embodiments of the present disclosure. For clarify, FIGS. 1-6 only show some elements for illustrative purpose, while other elements of the electronic device are omitted. In some embodiments, additional features may be added to the electronic device 10 described below. In some embodiments, some features of the electronic device 10 described below may be replaced or eliminated. In some embodiments, additional operating steps may be provided before, during, and/or after the method of forming the electronic device 10. In some embodiments, some of the operating steps described may be replaced or eliminated, and the order of some operating steps described may be interchanged.

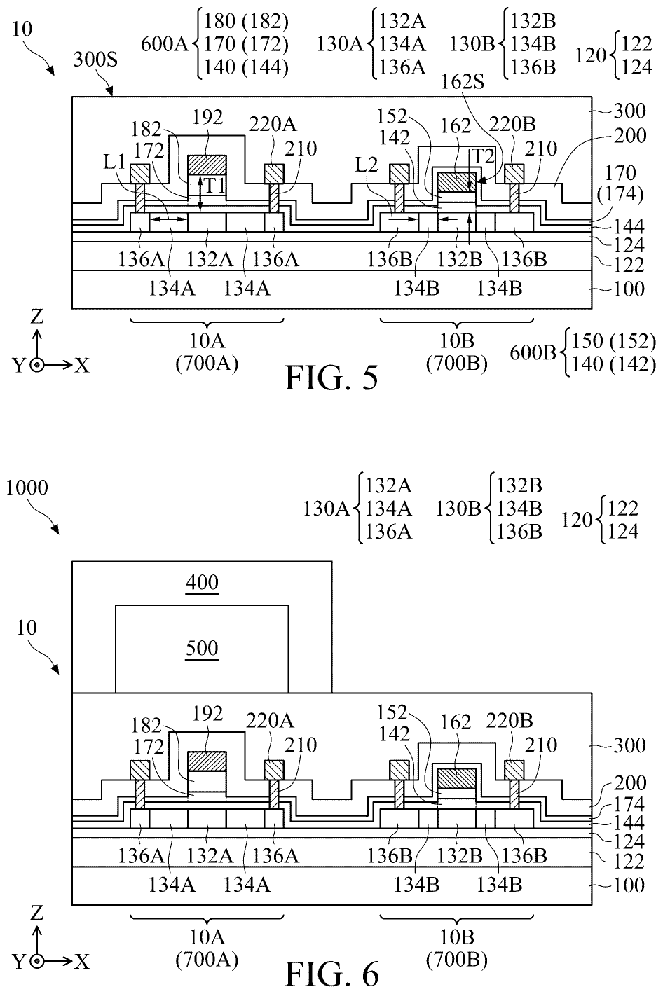

In some embodiments, the electronic device 10 may include a first element region 10A and a second element region 10B, as shown in FIG. 4. The subsequently formed first electronic element (for example, a first transistor 700A) and second electronic element (for example, a second transistor 700B) may be disposed within the first element region 10A and the second element region 10B, respectively (referring to FIG. 5). The first transistor 700A and the second transistor 700B may serve as the high-voltage electronic element and the low-voltage electronic element of the electronic device 10, respectively. In other words, the operating voltage of the first transistor 700A may be higher than the operating voltage of the second transistor 700B.

Referencing FIG. 1, a substrate 100 may be provided at the initial stage. According to some embodiments of the present disclosure, the substrate 100 may include a rigid substrate, a flexible substrate, the like, or a combination thereof. The rigid substrate may include, for example, glass. Materials of the flexible substrate may include transparent resins, such as polyethylene terephthalate (PET) resin, polycarbonate (PC) resin, polyimide (PI) resin, polymethyl methacrylate (PMMA), polystyrene resin, polyether sulfone (PES) resin, polythiophene (PT) resin, phenol novolac (PN), the like, or a combination thereof, but the present disclosure is not limited thereto. The materials of the flexible substrate may also include silicon oxide (SiO), silicon nitride (SiN), silicon carbide (SiC), silicon carbonitride (SiCN), silicon oxynitride (SiON), silicon oxynitrocarbide (SiOₓN_{y}C_{1-x-y}, where x and y are in the range of 0 to 1), the like, or a combination thereof, but the present disclosure is not limited thereto. In other embodiments, the substrate 100 may be an opaque substrate.

Still referring to FIG. 1, a buffer structure 120 may be disposed on a surface S1 of the substrate 100. The surface S1 of the substrate 100 may be a plane constituted by a first direction (X-axis) and a second direction (Y-axis). The third direction (Z-axis) may be the thickness direction of the substrate 100. The first direction (X-axis), the second direction (Y-axis), and the third direction (Z-axis) are distinct from each other. For example, the first direction may be perpendicular to the second direction, the second direction may be perpendicular to the third direction, and the first direction may be perpendicular to the third direction.

In some embodiments, the buffer structure 120 may include an insulating layer 122 and an insulating layer 124. According to some embodiments of the present disclosure, the buffer structure 120 may alleviate the strain of the overlying first semiconductor layer 130A and second semiconductor layer 130B that will be subsequently formed on the buffer structure 120 to prevent the formation of defects in the overlying first semiconductor layer 130A and second semiconductor layer 130B. The strain may be caused by a mismatch between the first semiconductor layer 130A/the second semiconductor layer 130B and the underlying film layers. In some embodiments, the insulating layer 122 and the insulating layer 124 may include organic materials, inorganic materials, or a combination thereof. Inorganic materials may include silicon oxide, silicon nitride, silicon carbide, silicon carbonitride, silicon oxynitride, silicon oxynitrocarbide, or a combination thereof. The insulating layer 122 and the insulating layer 124 may include different materials.

In some embodiments, the thickness of the insulating layer 122 may be between 0 Å and 3000 Å, for example, between 50 Å and 3000 Å. The thickness of the insulating layer 124 may be between 500 Å and 3000 Å. The insulating layer 122 and the insulating layer 124 of the buffer structure 120 may be formed by spin-on coating, chemical vapor deposition (CVD), high-density plasma chemical vapor deposition (HDP-CVD), plasma-enhanced chemical vapor deposition (PECVD), flowable chemical vapor deposition (FCVD), sub-atmospheric chemical vapor deposition (SACVD), low-pressure chemical vapor deposition (LPCVD), atomic layer deposition (ALD), the like, or a combination thereof, but the present disclosure is not limited thereto.

Referring to FIG. 1, a semiconductor layer (not shown) may be disposed on the buffer structure 120. The semiconductor layer is patterned to form the first semiconductor layer 130A and the second semiconductor layer 130B within the first element region 10A and the second element region 10B, respectively. The patterning method on various film layers in the present disclosure may adopt lithography process and etching process. The lithography process may include photoresist coating, soft baking, exposure, post-exposure baking, development, the like, or a combination thereof. The etching process may include wet etch process, dry etch process, the like, or a combination thereof.

In some embodiments, the thicknesses of the first semiconductor layer 130A and the second semiconductor layer 130B may be between 200 Å and 800 Å. Materials of the first semiconductor layer 130A and the second semiconductor layer 130B may include polysilicon, amorphous silicon, elemental semiconductors, compound semiconductors, alloy semiconductors, or a combination thereof. Elemental semiconductors may include silicon (Si) or germanium (Ge). Compound semiconductors may include gallium nitride (GaN), silicon carbide, gallium arsenide (GaAs), gallium phosphide (GaP), indium phosphide (InP), indium arsenide (InAs), and/or indium antimonide (InSb). Alloy semiconductors may include silicon germanium (SiGe) alloys, gallium arsenide phosphide (GaAsP) alloys, aluminum indium arsenide (AlInAs) alloys, aluminum gallium arsenide (AlGaAs) alloys, indium gallium arsenide (InGaAs) alloys, indium gallium phosphide (InGaP) alloys, and/or indium gallium arsenide phosphide (InGaAsP) alloys, or a combination thereof.

Still referring to FIG. 1, an insulating layer 140 may be disposed on the first semiconductor layer 130A and the second semiconductor layer 130B. In some embodiments, the insulating layer 140 may cover the buffer structure 120, the first semiconductor layer 130A, and the second semiconductor layer 130B. According to some embodiments of the present disclosure, the insulating layer 140 may constitute a portion of the subsequently formed first insulating structure 600A of the first transistor 700A, and a portion of the subsequently formed second insulating structure 600B of the second transistor 700B. The suitable materials and process for the insulating layer 140 may be referred to the previously described insulating layers, and the details are not described again herein to avoid repetition. The thickness of the insulating layer 140 may be between 500 Å to 1500 Å.

Referring to FIG. 1, an insulating layer 150 may be disposed on the insulating layer 140. According to some embodiments of the present disclosure, the insulating layer 150 may serve as another portion of the subsequently formed second insulating structure 600B of the second transistor 700B. The suitable materials and process for the insulating layer 150 may be referred to the previously described insulating layers. In a specific embodiment of the present disclosure, the insulating layer 150 may include silicon nitride. The thickness of the insulating layer 150 may be between 100 Å and 1000 Å.

Still referring to FIG. 1, a gate layer 160 may be disposed on the insulating layer 150. Materials of the gate layer 160 may include metals, metal alloys, amorphous silicon, polysilicon, polycrystalline silicon germanium (poly-SiGe), metal nitrides (such as titanium nitride (TiN), tantalum nitride (TaN), tungsten nitride (WN), titanium aluminum nitride (TiAlN), or the like), metal silicides (such as nickel silicide (NiSi), cobalt silicide (CoSi), tantalum silicon nitride (TaSiN), or the like), metal carbides (such as tantalum carbide (TaC), tantalum carbonitride (TaCN), or the like), metal oxides, or a combination thereof. Metals may include cobalt (Co), ruthenium (Ru), aluminum (Al), tungsten (W), copper (Cu), titanium (Ti), tantalum (Ta), silver (Ag), gold (Au), platinum (Pt), nickel (Ni), palladium (Pd), zinc (Zn), chromium (Cr), molybdenum (Mo), niobium (Nb), beryllium (Be), strontium (Sr), the like, a combination thereof, or a multiple layer thereof, but the present disclosure is not limited thereto.

In some embodiments, the thickness of the gate layer 160 may be between 1000 Å and 4000 Å. The gate layer 160 may be formed by physical vapor deposition (PVD), atomic layer deposition, plating, evaporating, sputtering, the like, or a combination thereof.

Referring to FIG. 2, the gate layer 160 is patterned to form a second gate 162 within the second element region 10B. Next, the insulating layer 150 below the second gate 162 is patterned using the second gate 162 as the mask. For example, a main etching and an over etching may be sequentially used to pattern the insulating layer 150. The main etching may use, for example, sulfur hexafluoride (SF₆) and chlorine (Cl₂) to remove the portion of the insulating layer 150 not being covered by the second gate 162, and the remaining portion of the insulating layer 150 being covered by the second gate 162 becomes the insulating layer 152. The over etching may use, for example, chlorine and oxygen (O₂) to ensure the portion of the insulating layer 150 not being covered by the second gate 162 may be completely removed. Also, the over etching may cause the portion of the insulating layer 140 not being covered by the second gate 162 to be etched, leading to a reduction in thickness for the insulating layer 140, which becomes an insulating layer 144. The insulating layer 140 after etching may include an insulating layer 142 being covered by the second gate 162, as well as the insulating layer 144 not being covered by the second gate 162. The thickness of the insulating layer 142 may remain the same with the thickness of the insulating layer 140. The thickness of the insulating layer 144 may be between 100 Å and 1200 Å. The thickness of the insulating layer 144 may be less than the thickness of the insulating layer 142. It should be appreciated that the insulating layer 142 and the insulating layer 152 may collectively serve as the subsequently formed second insulating structure 600B of the second transistor 700B (referring to FIG. 5). The second insulating structure 600B of the second transistor 700B may have a thickness T2 (shown in FIG. 4), and the thickness T2 may be between 600 Å and 2500 Å.

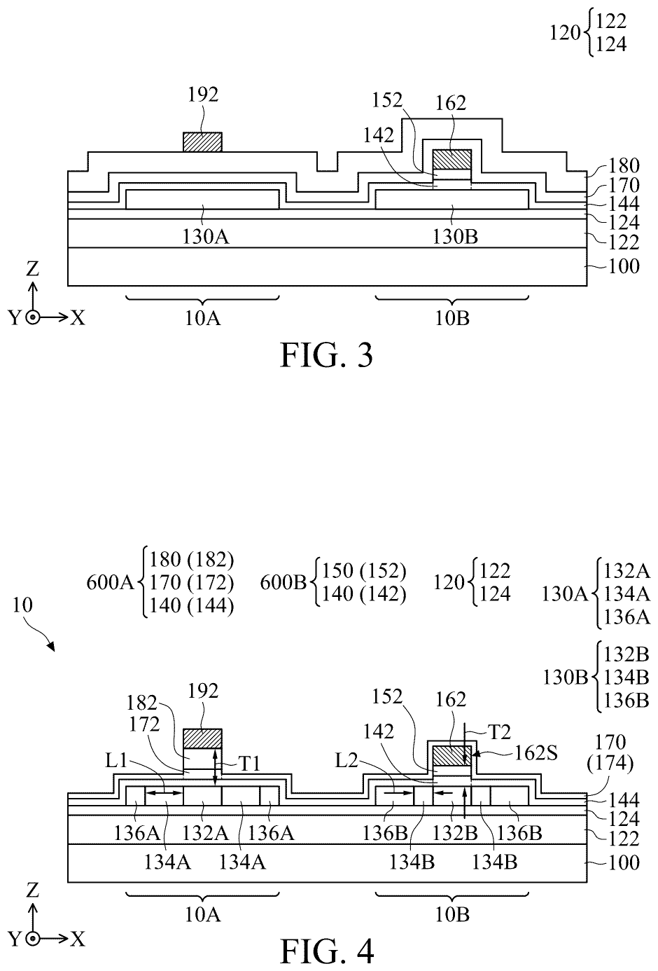

Referring to FIG. 3, an insulating layer 170 may be formed on the intermediate structure. In some embodiments, the insulating layer 170 may cover the insulating layer 142, the insulating layer 144, the insulating layer 152, and the second gate 162. According to some embodiments of the present disclosure, the insulating layer 170 may protect the second insulating structure 600B and the second gate 162 of the second transistor 700B from the subsequent manufacturing process of the first transistor 700A within the first element region 10A. The suitable materials and process for the insulating layer 170 may be referred to the previously described insulating layers. The thickness of the insulating layer 170 may be between 50 Å to 2000 Å.

Still referring to FIG. 3, an insulating layer 180 may be formed on the insulating layer 170. The suitable materials and process for the insulating layer 180 may be referred to the previously described insulating layers. The thickness of the insulating layer 180 may be between 500 Å and 10000 Å.

Referring to FIG. 3, a gate layer (not shown) may be formed on the insulating layer 180, followed by patterning the gate layer to form a first gate 192. The thickness of the first gate 192 may be between 1000 Å and 4000 Å. Materials and the formation of the first gate 192 may be referred to the previously described second gate 162, and the details are not described again herein to avoid repetition.

Referring to FIG. 4, the insulating layer 180 below the first gate 192 may be patterned using the first gate 192 as a mask. For example, the main etching and the over etching may be sequentially used to pattern the insulating layer 180. The main etching may use, for example, sulfur hexafluoride and chlorine to remove the portion of the insulating layer 180 not being covered by the first gate 192, and the remaining portion of the insulating layer 180 being covered by the first gate 192 becomes the insulating layer 182. The insulating layer 182 may be disposed between the insulating layer 144 and the first gate 192. The over etching may use, for example, chlorine and oxygen to ensure the portion of the insulating layer 180 not being covered by the first gate 192 may be completely removed. Also, the over etching may cause the portion of the insulating layer 170 not being covered by the first gate 192 to be etched, leading to a reduction in thickness for the insulating layer 170, which becomes an insulating layer 174. The insulating layer 170 after etching may include an insulating layer 172 being covered by the first gate 192, and the insulating layer 174 not being covered by the first gate 192. The thickness of the insulating layer 172 may remain the same with the thickness of the insulating layer 170. The thickness of the insulating layer 174 may be less than the thickness of the insulating layer 172. The thickness of the insulating layer 174 may be between 50 Å and 500 Å. It should be appreciated that the insulating layer 144 (the insulating layer 140), the insulating layer 172 (the insulating layer 170), and the insulating layer 182 (the insulating layer 180) may collectively serve as the subsequently formed first insulating structure 600A of the first transistor 700A (referring to FIG. 5). The first insulating structure 600A of the first transistor 700A may have a thickness T1, and the thickness T1 may be between 1000 Å and 10000 Å.

According to some embodiments of the present disclosure, the thickness T1 of the first insulating structure 600A of the first transistor 700A may be larger than the thickness T2 of the second insulating structure 600B of the second transistor 700B, as shown in FIG. 5. In the first transistor 700A, the first insulating structure 600A may be disposed between the first semiconductor layer 130A and the first gate 192. In the second transistor 700B, the second insulating structure 600B may be disposed between the second semiconductor layer 130B and the second gate 162. The second gate 162 and the first gate 192 may be located in different film levels. More specifically, the distance between the second gate 162 and the substrate 100 is different from the distance between the first gate 192 and the substrate 100 in the third direction (Z-axis).

As mentioned previously, the portion of the insulating layer 170 not being covered by the first gate 192 is etched, leading to a reduction in thickness for the insulating layer 170, which becomes the insulating layer 174, as shown in FIG. 4. In the second element region 10B, the insulating layer 174 may be disposed on a sidewall 162S of the second gate 162, and on the upper surface of the second gate 162.

According to some embodiments, the insulating layer 180 below the first gate 192 may adopt silicon nitride, and the insulating layer 150 below the second gate 162 may also adopt silicon nitride. According to some embodiments, the thickness of insulating layer 180 may be larger than the thickness of insulating layer 170, and may also be larger than the thickness of the insulating layer 140 in the first insulating structure 600A. In the second insulating structure 600B, the thickness of insulating layer 150 may be larger than the thickness of insulating layer 140. As such, the insulating layer 180 and the insulating layer 150 may provide more superior self-alignment precision during the subsequent ion implantation process for the first semiconductor layer 130A and the second semiconductor layer 130B. According to some embodiments, a more superior self-alignment precision may be provided by directly using the insulating layer 180 and the insulating layer 150 as masks without applying additional photomask.

In some embodiments, the insulating layer 174 exposed by the first gate 192 and the insulating layer 182 may adopt silicon oxide, while the insulating layer 144 exposed by the second gate 162 and the insulating layer 152 may adopt silicon oxide. This configuration facilitates the subsequent ion implantation processes.

Still referring to FIG. 4, the ion implantation process may be performed on the first semiconductor layer 130A within the first element region 10A and the second semiconductor layer 130B within the second element region 10B. The region in the first semiconductor layer 130A corresponding to the first gate 192 may become a channel region 132A. The region in the second semiconductor layer 130B corresponding to the second gate 162 may become a channel region 132B. The channel region 132A and the channel region 132B may be the portion in the first semiconductor layer 130A not being implanted and the portion in the second semiconductor layer 130B not being implanted, respectively. The channel region 132A and the channel region 132B may serve as the channels for the transistors.

Initially, a first ion implantation process may be performed on opposite sides of the channel region 132A within the first element region 10A and on opposite sides of the channel region 132B within the second element region 10B (the portion of the first semiconductor layer 130A not being covered by the first gate 192 and the portion of the second semiconductor layer 130B not being covered by the second gate 162) to form a lightly doped region 134A and a lightly doped region 134B. Next, a second ion implantation process may be performed on the portion of the lightly doped region 134A close to the edge of the first semiconductor layer 130A in the first element region 10A, and the portion of the lightly doped region 134B close to the edge of the second semiconductor layer 130B in the second element region 10B, in order to respectively form a heavily doped region 136A and a heavily doped region 136B. In the first element region 10A, the heavily doped region 136A may be positioned at opposite sides of the first gate 192. In the second element region 10B, the heavily doped region 136B may be positioned at opposite sides of the second gate 162. The lightly doped region 134A in the first element region 10A may be disposed between the channel region 132A and the heavily doped region 136A, while the lightly doped region 134B in the second element region 10B may be disposed between the channel region 132B and the heavily doped region 136B. The concentration of the heavily doped region 136A may be larger than the concentration of the lightly doped region 134A. The concentration of the heavily doped region 136B may be larger than the concentration of the lightly doped region 134B.

In the embodiments described below, the implanted ions may be p-type or n-type. A p-type region or an n-type region may be respectively doped with appropriate dopants (or impurities). The p-type dopants may include boron (B), indium (In), aluminum, or gallium (Ga), while the n-type dopants may include phosphorus (P) or arsenic (As).

As shown in FIG. 4, the lightly doped region 134A of the first element region 10A may have a length L1, while the lightly doped region 134B of the second element region 10B may have a length L2. According to some embodiments of the present disclosure, the length L1 of the lightly doped region 134A may be larger than the length L2 of the lightly doped region 134B. The larger length of the lightly doped region 134A of the first transistor 700A may reduce the horizontal electric field generated during operation, which in turn enhances the resistivity of the lightly doped region 134A of the first transistor 700A to sustain high voltages.

In some embodiment, the concentration of the lightly doped region 134A of the first transistor 700A may be lower than the concentration of the lightly doped region 134B of the second transistor 700B. Based on such design, the light doped regions of different concentrations need to be formed in different processes. The lower concentration of the lightly doped region 134A of the first transistor 700A may reduce the horizontal electric field generated during operation. Due to the positive correlation between the doping concentration of the lightly doped region 134A and the conductivity, the lower concentration of the lightly doped region 134A of the first transistor 700A may reduce the conductivity, which in turn enhances the resistivity of the lightly doped region 134A of the first transistor 700A to sustain high voltages.

In some embodiments, the concentration of the heavily doped region 136A of the first transistor 700A may be equal to the concentration of the heavily doped region 136B of the second transistor 700B. Therefore, the heavily doped region 136A of the first transistor 700A and the heavily doped region 136B of the second transistor 700B may be simultaneously formed in a single process. Through the mask design, the heavily doped region 136A in the first transistor 700A and the heavily doped region 136B in the second transistor 700B may have different lengths, which in turn creates the desired length L1 of the lightly doped region 134A in the first transistor 700A and the desired length L2 of the lightly doped region 134B in the second transistor 700B.

Referring to FIG. 5, an interlayer dielectric (ILD) layer 200 may be formed within the first element region 10A and the second element region 10B. In some embodiments, the interlayer dielectric layer 200 may cover the insulating layer 172, the insulating layer 174, the insulating layer 182, and the first gate 192. According to some embodiments of the present disclosure, in addition to providing mechanical protection and electrical insulation for the underlying structures, the interlayer dielectric layer 200 may also isolate conductive materials from different levels. The suitable materials and process for the interlayer dielectric layer 200 may be referred to the previously described insulating layers. Furthermore, the interlayer dielectric layer 200 may include tetra ethyl ortho silicate (TEOS), undoped silicate glass, doped silicon oxide (such as boron-doped phospho-silicate glass (BPSG), fused silica glass (FSG), phosphosilicate glass (PSG), boron doped silicon glass (BSG), or the like), low-k dielectric materials, or the like. The thickness of the interlayer dielectric layer 200 may be between 500 Å and 5000 Å.

Still referring to FIG. 5, vias 210 may be formed through the interlayer dielectric layer 200, the insulating layer 174, and the insulating layer 144. An electrode layer (not shown) may be formed on the interlayer dielectric layer 200, followed by patterning the electrode layer to form a source/drain 220A and a source/drain 220B. According to some embodiments, the source/drain 220A, the source/drain 220B, and the vias 210 may be the same material. According to some embodiments, the material of the vias 210 may be different from the material of the source/drain 220A and the source/drain 220B. The source/drain 220A may be electrically connected to the heavily doped region 136A in the first transistor 700A through the vias 210. For example, the vias 210 may be electrically connected (for example, in direct contact) with the heavily doped region 136A. The source/drain 220B may be electrically connected to the heavily doped region 136B in the second transistor 700B through the vias 210. For example, the vias 210 may be electrically connected (for example, in direct contact) with the heavily doped region 136B. According to some embodiments of the present disclosure, the operating voltages may be respectively applied to the source/drain 220A and the source/drain 220B. Materials and the formation of the vias 210, the source/drain 220A, and the source/drain 220B may be referred to the previously described second gate 162 and first gate 192, and the details are not described again herein to avoid repetition. The thickness of the source/drain 220A and the source/drain 220B may be between 1000 Å and 8000 Å.

At this point, the fabrication of the first transistor 700A and the second transistor 700B has been completed. Within the first element region 10A, the first transistor 700A may include the first semiconductor layer 130A, the first gate 192, the source/drain 220A, and the first insulating structure 600A disposed between the first semiconductor layer 130A and the first gate 192. Within the second element region 10B, the second transistor 700B may include the second semiconductor layer 130B, the second gate 162, the source/drain 220B, and the second insulating structure 600B disposed between the second semiconductor layer 130B and the second gate 162. For the same semiconductor layer, the first gate 192 and the second gate 162 may be disposed on the same side of the semiconductor layer. Specifically, the first gate 192 and the first insulating structure 600A may be disposed on the upper surface of the semiconductor layer, while the second gate 162 and the second insulating structure 600B may also be disposed on the upper surface of the semiconductor layer.

Such configuration allows the first transistor 700A and the second transistor 700B to be simultaneously disposed on the same substrate 100. The thickness T1 of the first insulating structure 600A in the first transistor 700A may be greater than the thickness T2 of the second insulating structure 600B in the second transistor 700B. The larger thickness of the first insulating structure 600A may reduce the vertical electric field generated during operation, so the first transistor 700A may withstand higher voltages. Therefore, the first transistor 700A may be suitable for the high-voltage operation. The first transistor 700A has the first operating voltage, while the second transistor 700B has the second operating voltage, where the first operating voltage is higher than the second operating voltage. The first operating voltage may be between 30V and 100V, for example, between 40V and 90V, or between 40V and 80V. The second operating voltage may be between 5V and 30V, for example, between 8V and 25V, or between 8V and 22V. The difference between the first operating voltage and the second operating voltage may be between 5V and 95V.

As shown in FIG. 5, the thickness T1 of the first insulating structure in the first transistor may be designed to be larger than the thickness T2 of the second insulating structure in the second transistor, and the length L1 of the lightly doped region 134A of the first semiconductor layer in the first transistor may be designed to be larger than the length L2 of the lightly doped region 134B of the second semiconductor layer in the second transistor. According to some embodiments (though not shown), the thickness T1 of the first insulating structure in the first transistor may be designed to be larger than the thickness T2 of the second insulating structure in the second transistor, and the length L1 of the lightly doped region 134A of the first semiconductor layer in the first transistor may be designed to be equal to or shorter than the length L2 of the lightly doped region 134B of the second semiconductor layer in the second transistor. According to some embodiments (though not shown), the length L1 of the lightly doped region 134A of the first semiconductor layer in the first transistor may be designed to be larger than the length L2 of the lightly doped region 134B of the second semiconductor layer in the second transistor, and the thickness T1 of the first insulating structure in the first transistor may be designed to be equal to or less than the thickness T2 of the second insulating structure in the second transistor.

Referring to FIG. 5, an insulating layer 300 may be formed on the interlayer dielectric layer 200. The suitable materials and processes of the insulating layer 300 may be referred to the previously described insulating layers. The thickness of the insulating layer 300 may be between 1 μm and 3 μm. According to some embodiments, a surface 300S of the insulating layer 300 may be planar. Alternatively, a planarization process (such as chemical mechanical polish (CMP)) may be performed on the insulating layer 300 to planarize the surface 300S of the insulating layer 300 after the formation of the insulating layer 300, according to some embodiments.

Referring to FIG. 6, a piezoelectric unit 400 may be formed on the insulating layer 300 within the first element region 10A. In some embodiments, the piezoelectric unit 400 may be flip-attached to the electronic device 10, particularly corresponding to the first transistor 700A. The assembled structure may result a cavity 500 between the insulating layer 300 and the piezoelectric unit 400. According to some embodiments of the present disclosure, the electronic device 10, the piezoelectric unit 400, and the cavity 500 may collectively constitute a piezoelectric micro-machined ultrasonic transducer (pMUT) 1000. The piezoelectric unit 400 may be electrically connected to the first transistor 700A within the first element region 10A. The piezoelectric unit 400 may be driven by the first transistor 700A in order to vibrate. Ultrasonic wave signals may thus be transmitted or received. When the ultrasonic wave signals are transmitted, the piezoelectric micro-machined ultrasonic transducer 1000 may act as a transmitter. When the ultrasonic wave signals are received, the piezoelectric micro-machined ultrasonic transducer 1000 may act as a sensor.

In the medical field, the piezoelectric micro-machined ultrasonic transducer 1000 may be designed into a wearable electronic product. The piezoelectric unit 400 may be vibrated to generate the ultrasonic wave signals through driving the first transistor 700A. The ultrasonic wave signals may be transmitted into a human body reaching the organs that needs to be examined. After reaching the organs, another ultrasonic wave signal will be reflected back to the piezoelectric micro-machined ultrasonic transducer 1000. The other ultrasonic wave signal may be read by the piezoelectric micro-machined ultrasonic transducer 1000 similarly through vibrating of the piezoelectric unit 400, which in turn determines the condition of the organs being examined.

During the manufacturing process of the piezoelectric micro-machined ultrasonic transducer 1000, the scanning electron microscope may be used to analyze the thicknesses of the insulating structures of the first transistor 700A and the second transistor 700B, while a scanning capacitance microscope (SCM) may be used to analyze the length L1 of the lightly doped region 134A of the first transistor 700A and the length L2 of the lightly doped region 134B of the second transistor 700B. During the operation of the piezoelectric micro-machined ultrasonic transducer 1000, a test element group (TEG) may be used to measure the breakdown voltages of the first transistor 700A and the second transistor 700B, while an oscilloscope may be used to measure the operating voltages of the first transistor 700A and the second transistor 700B. The breakdown voltage of the first transistor 700A may be between 100V and 300V. The breakdown voltage of the second transistor 700B may be between 50V and 150V.

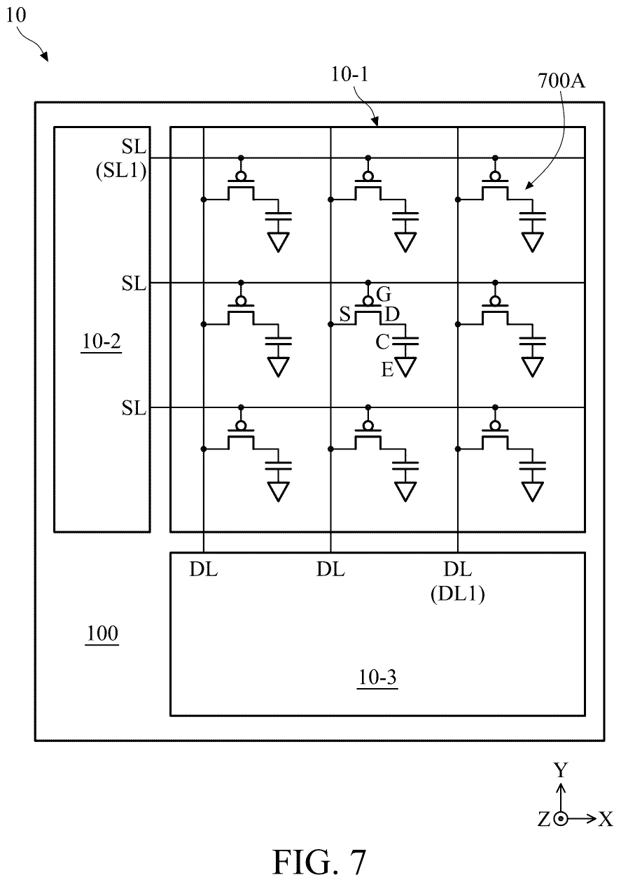

FIG. 7 is a top view of the electronic device 10, according to some embodiments of the present disclosure. The substrate 100 may include an active region 10-1 and a peripheral region. The peripheral region may be adjacent to the active region 10-1. For example, the peripheral region may be disposed at the periphery of the active region 10-1. The first transistor 700A and the second transistor 700B may be disposed within the active region 10-1 and the peripheral region, respectively. According to some embodiments, the peripheral region may further include a gate circuit region 10-2 and an integrated circuit region 10-3. The second transistor 700B may be disposed within the gate circuit region 10-2. A plurality of scan lines SL and a plurality of data lines DL may be disposed within the active region 10-1. The plurality of scan lines SL and the plurality of data lines DL may be disposed intersecting each other. For example, the plurality of scan lines SL may be extended along the first direction (X-axis), while the plurality of data lines DL may be extended along the second direction (Y-axis). Other elements in FIGS. 1-6 are omitted, for simplicity.

Referring to FIGS. 5 and 7, using a scan line SL1 and a data line DL1 as examples for illustration, the first transistor 700A may be electrically connected with the scan line SL1, and may be electrically connected with the data line DL1. The first transistor 700A may be electrically connected with the scan line SL1 through the first gate 192, and may be electrically connected with the data line DL1 through the source terminal of the source/drain 220A. According to some embodiments, the second transistor 700B may be disposed within the gate circuit region 10-2, and the scan line SL1 may electrically connect the first transistor 700A within the active region 10-1 with the second transistor 700B within the gate circuit region 10-2. According to some embodiments, the second transistor 700B may be disposed within the integrated circuit region 10-3, and the data line DL1 may electrically connect the first transistor 700A within the active region 10-1 with the second transistor 700B within the integrated circuit region 10-3.

Referring to FIG. 7, the active region 10-1 may also be considered as a pixel region of the electronic device 10. During the operation of the piezoelectric micro-machined ultrasonic transducer 1000, each pixel region may generate a respective ultrasonic wave signal. The pixel region may include an array of multiple thin film transistors. Although the multiple thin film transistors are illustrated as a 3×3 array, but the present disclosure is not limited thereto. The active region 10-1 may have m×n thin film transistors, in which m and n are positive integers that can be the same or different. In some embodiments, the thin film transistors in FIG. 7 may be the first transistor 700A shown in FIG. 5. The first transistor 700A may include a source terminal S, a drain terminal D, a gate terminal G, a capacitor C, and an external electrode E. The source terminal S and the drain terminal D in FIG. 7 may be corresponded to the source/drain 220A in FIG. 5. The gate terminal G in FIG. 7 may be corresponded to the first gate 192 in FIG. 5. The gate terminals G of the thin film transistors in each row may be electrically coupled by the scan lines SL, which are electrically connected to the gate circuit region 10-2. The source terminals S of the thin film transistors in each column may be electrically coupled by the data lines DL, which are electrically connected to the integrated circuit region 10-3. The operating voltage may be applied through the drain terminal D. The capacitor C may serve as the piezoelectric unit 400 of the piezoelectric micro-machined ultrasonic transducer 1000. The external electrode E may be electrically connected to the piezoelectric unit 400, but may not be electrically connected to the scan lines SL or the data lines DL.

Still referring to FIG. 7, the gate circuit region 10-2 can control the scan lines SL to drive the gate terminals G of the thin film transistors. The gate circuit region 10-2 may include a plurality of level shifters (not shown). The plurality of level shifters in the gate circuit region 10-2 may be arranged sequentially in the direction towards the active region 10-1. The plurality of level shifters may sequentially raise the voltage, in which the maximum voltage is input into the active region 10-1 from the level shifter closest to the active region 10-1. Therefore, the level shifters closer to the active region 10-1 may be considered as the high-voltage elements, while the remaining level shifters may be considered as the low-voltage elements.

Referring to FIG. 7, the integrated circuit region 10-3 can control the plurality of data lines DL to transmit or to receive signals. For example, a signal sent from the integrated circuit region 10-3 may vibrate the capacitor C to generate an ultrasonic wave signal into the human body. The human body may reflect another ultrasonic wave signal back and vibrate the capacitor C. The reflected signal may then be transmitted back to the integrated circuit region 10-3 through the thin film transistors for reception. Multiplexers (MUX) (not shown) may be disposed between the active region 10-1 and the integrated circuit region 10-3 to distribute the signal among every thin film transistor in the active region 10-1. Although the integrated circuit region 10-3 is illustrated to be inside the substrate 100, but the present disclosure is not limited thereto. For example, the integrated circuit region 10-3 may also be configured outside the substrate 100.

As stated above, the electronic device of the present disclosure allows the high-voltage element and the low-voltage element to be simultaneously configured onto the same substrate. According to some embodiments, the high-voltage element and the low-voltage element may be designed to sustain different voltages through adjusting the thicknesses of the insulating structures in the different elements. According to some embodiments, the high-voltage element and the low-voltage element may be designed to sustain different voltages through adjusting the lengths of the lightly doped regions in the different elements. According to some embodiments, the high-voltage element and the low-voltage element may be designed to sustain different voltages through adjusting the concentrations of the lightly doped regions in the different elements. In doing so, the high-voltage element and the low-voltage element may be operated simultaneously in the same electronic device. In the high-voltage element, increasing the length and/or decreasing the concentration of the lightly doped region may reduce the horizontal electric field to sustain higher voltages. Furthermore, in the high-voltage element, increasing the thickness of the insulating structure may reduce the vertical electric field to sustain higher voltages.

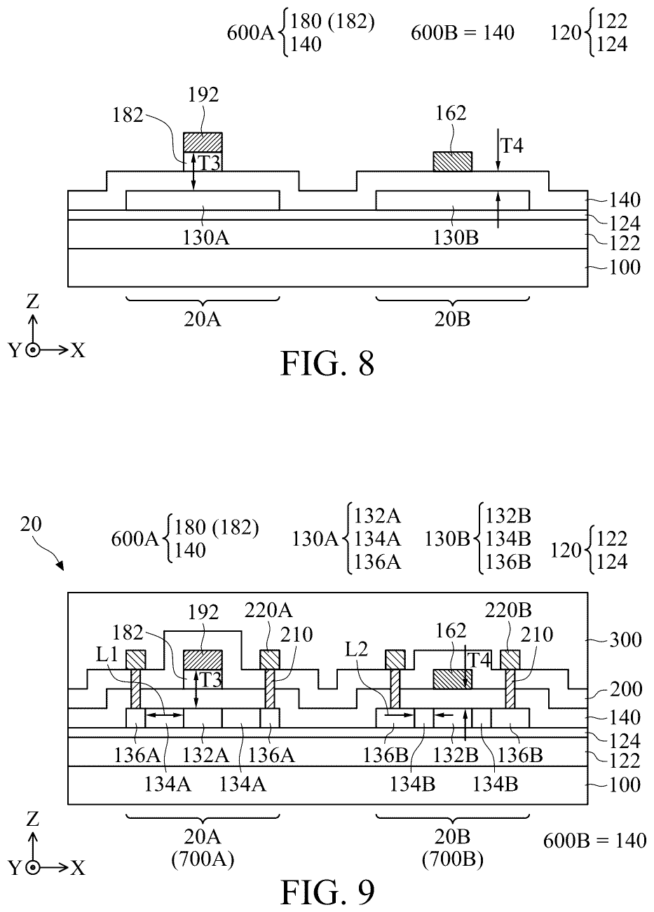

FIGS. 8 and 9 are various cross-sectional views of intermediate stages of an electronic device 20, according to some embodiments of the present disclosure. The electronic device 20 may include a first element region 20A and a second element region 20B. The subsequently formed first transistor 700A and second transistor 700B may be disposed within the first element region 20A and the second element region 20B, respectively (referring to FIG. 9). The first transistor 700A and second transistor 700B may respectively serve as the high-voltage element and the low-voltage element of the electronic device 20. In other words, the operating voltage of the first transistor 700A may be higher than the operating voltage of the second transistor 700B. In comparison with the electronic device 10, the first insulating structure 600A in the first transistor 700A of the electronic device 20 only includes the insulating layer 182 and the insulating layer 140. The second insulating structure 600B in the second transistor 700B of the electronic device 20 only includes the insulating layer 140, and the insulating layer 150 is omitted. For simplicity, the features of the substrate 100, the buffer structure 120 (including the insulating layer 122 and the insulating layer 124), the first semiconductor layer 130A, the second semiconductor layer 130B, and the insulating layer 140 are similar to those illustrated in FIG. 1, and the details are not described again herein to avoid repetition.

Referring to FIG. 8, the insulating layer 150 is not formed, in comparison with FIG. 2. The insulating layer 140 may adopt silicon oxide. In the present embodiment, the thickness of the insulating layer 140 may be between 500 Å and 1500 Å.

Still referring to FIG. 8, the insulating layer 180 may be formed on the insulating layer 140. The insulating layer 180 may include silicon nitride. The thickness of the insulating layer 180 may be between 1000 Å and 10000 Å.

Referring to FIG. 8, the first gate 192 may be formed on the insulating layer 180. After that, the insulating layer 180 is patterned using the first gate 192 as the mask to remove the portion of the insulating layer 180 not being covered by the first gate 192. The remaining portion of the insulating layer 180 being covered by the first gate 192 becomes the insulating layer 182.

It should be appreciated that the insulating layer 140 may serve as the second insulating structure 600B of the second transistor 700B, while the insulating layer 140 and the insulating layer 182 may collectively serve as the first insulating structure 600A of the first transistor 700A. The first insulating structure 600A of the first transistor 700A may have a thickness T3, and the thickness T3 may be between 2000 Å and 10000 Å. The second insulating structure 600B of the second transistor 700B may have a thickness T4, and the thickness T4 may maintain the same thickness as the insulating layer 140. The thickness T3 of the first insulating structure 600A of the first transistor 700A may be larger than the thickness T4 of the second insulating structure 600B of the second transistor 700B. The insulating layer 140 may be disposed between the substrate 100 and the second gate 162, as well as between the substrate 100 and the first gate 192, as shown in FIG. 8.

Referring to FIG. 9, an ion implantation process may be performed on the first semiconductor layer 130A of the first transistor 700A and the second semiconductor layer 130B of the second transistor 700B, which is similar to the previously described ion implantation process in FIG. 4. In some embodiments, the channel region 132A, the lightly doped region 134A, and the heavily doped region 136A may be formed in the first semiconductor layer 130A, while the channel region 132B, the lightly doped region 134B, and the heavily doped region 136B may be formed in the second semiconductor layer 130B. The region of the first semiconductor layer 130A corresponding to the first gate 192 may be the channel region 132A. The region of the second semiconductor layer 130B corresponding to the second gate 162 may be the channel region 132B. According to some embodiments, the length L1 of the lightly doped region 134A of the first transistor 700A may be larger than the length L2 of the lightly doped region 134B of the second transistor 700B. According to some embodiments, the concentration of the lightly doped region 134A of the first transistor 700A may be lower than the concentration of the lightly doped region 134B of the second transistor 700B.

Still referring to FIG. 9, the interlayer dielectric layer 200, the vias 210, the source/drain 220A, the source/drain 220B, and the insulating layer 300 may be sequentially formed, which is similar to the previously described process in FIG. 5, and the details are not described again herein to avoid repetition. In some embodiments, the interlayer dielectric layer 200 may cover the insulating layer 140, the second gate 162, the insulating layer 182, and the first gate 192. It should be appreciated that, similar to FIG. 6 described above, the electronic device 20 may also be combined with the piezoelectric unit 400 and the cavity 500 to constitute the piezoelectric micro-machined ultrasonic transducer (not shown for simplicity).

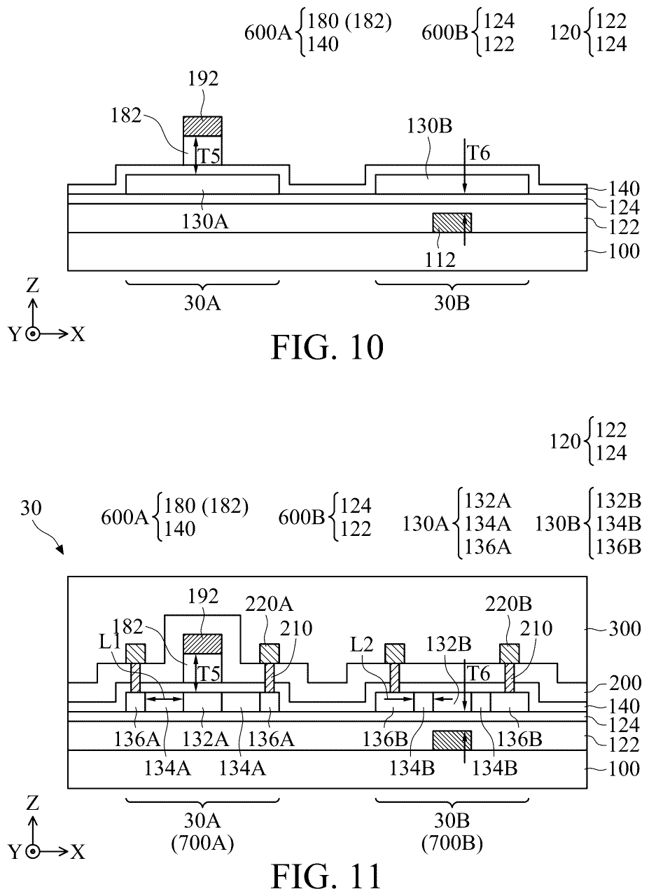

FIGS. 10 and 11 are various cross-sectional views of intermediate stages of an electronic device 30, according to some embodiments of the present disclosure. The electronic device 30 may include a first element region 30A and a second element region 30B. The subsequently formed first transistor 700A and second transistor 700B may be disposed within the first element region 30A and the second element region 30B, respectively (referring to FIG. 11). The first transistor 700A and second transistor 700B may respectively serve as the high-voltage element and the low-voltage element of the electronic device 30. In other words, the operating voltage of the first transistor 700A may be higher than the operating voltage of the second transistor 700B. In comparison with the electronic device 10 and the electronic device 20, a second gate 112 in the second transistor 700B of the electronic device 30 may be disposed below the second semiconductor layer 130B. For simplicity, the features of the substrate 100, the buffer structure 120 (including the insulating layer 122 and the insulating layer 124), the first semiconductor layer 130A, and the second semiconductor layer 130B are similar to those illustrated in FIG. 1, and the details are not described again herein to avoid repetition. For the same semiconductor layer, the first gate 192 and the second gate 112 may be disposed at different sides of the semiconductor layer. Specifically, the first gate 192 and the first insulating structure 600A may be disposed on the upper surface of the semiconductor layer, while the second gate 112 and the second insulating structure 600B may be disposed on the lower surface of the semiconductor layer.

Referring to FIG. 10, the second gate 112 may be formed on the substrate 100 before the formation of the buffer structure 120. According to some embodiments of the present disclosure, the second gate 112 may serve as the gate line of the subsequently formed second transistor 700B. It should be appreciated that the second gate 162 of the electronic device 10 and the electronic device 20 may be a top-gate design, while the second gate 112 of the electronic device 30 may be a bottom-gate design. The second semiconductor layer 130B in the second transistor 700B of the electronic device 10 may be disposed between the substrate 100 and the second gate 162, while the second gate 112 in the second transistor 700B of the electronic device 30 may be disposed between the substrate 100 and the second semiconductor layer 130B.

Still referring to FIG. 10, the insulating layer 140, the insulating layer 180, and the first gate 192 may be sequentially formed on the first semiconductor layer 130A and the second semiconductor layer 130B. According to some embodiments of the present disclosure, the insulating layer 140 and the insulating layer 180 may serve as the subsequently formed first insulating structure 600A of the first transistor 700A. The thickness of the insulating layer 140 may be between 500 Å and 1500 Å. The thickness of the insulating layer 180 may be between 500 Å and 10000 Å. Materials and the formation of the insulating layer 140, the insulating layer 180, and the first gate 192 are similar to those illustrated in FIG. 3, and the details are not described again herein to avoid repetition.

Referring to FIG. 10, the first gate 192 may be used as the mask to remove the portion of the insulating layer 180 not being covered by the first gate 192. The remaining portion of the insulating layer 180 being covered by the first gate 192 becomes the insulating layer 182. The formation of the insulating layer 182 is similar to that illustrated in FIG. 4, and the details are not described again herein to avoid repetition.

It should be appreciated that in addition to serve as the buffer structure, the insulating layer 122 and the insulating layer 124 may also act as the second insulating structure 600B of the second transistor 700B. The insulating layer 140 and the insulating layer 182 may collectively serve as the first insulating structure 600A of the first transistor 700A. The first insulating structure 600A of the first transistor 700A may have a thickness T5, and the thickness T5 may be between 1000 Å and 11500 Å. The second insulating structure 600B of the second transistor 700B may have a thickness T6. The thickness T5 of the first insulating structure 600A of the first transistor 700A may be larger than the thickness T6 of the second insulating structure 600B of the second transistor 700B. The insulating layer 140 may be disposed between the substrate 100 and the first gate 192. Moreover, the insulating layer 180 may be patterned to obtain the insulating layer 182. The first insulating structure 600A of the first transistor 700A may include the insulating layer 140 and the insulating layer 182. The insulating layer 182 may be disposed between the insulating layer 140 and the first gate 192.

Referring to FIG. 11, an ion implantation process may be performed on the first semiconductor layer 130A of the first transistor 700A and the second semiconductor layer 130B of the second transistor 700B, which is similar to the previously described ion implantation process in FIG. 4. In some embodiments, the channel region 132A, the lightly doped region 134A, and the heavily doped region 136A may be formed in the first semiconductor layer 130A, while the channel region 132B, the lightly doped region 134B, and the heavily doped region 136B may be formed in the second semiconductor layer 130B. The first gate 192 may be disposed corresponding to the channel region 132A of the first transistor 700A, while the second gate 112 may be disposed corresponding to the channel region 132B of the second transistor 700B. In some embodiments, the length L1 of the lightly doped region 134A of the first transistor 700A may be larger than the length L2 of the lightly doped region 134B of the second transistor 700B. In some embodiments, the concentration of the lightly doped region 134A of the first transistor 700A may be lower than the concentration of the lightly doped region 134B of the second transistor 700B.

Still referring to FIG. 11, the interlayer dielectric layer 200, the vias 210, the source/drain 220A, the source/drain 220B, and the insulating layer 300 may be sequentially formed, which is similar to the previously described process in FIG. 5. In some embodiments, the interlayer dielectric layer 200 may cover the insulating layer 140, the insulating layer 182, and the first gate 192. After that, the insulating layer 300 may be formed on the interlayer dielectric layer 200, and the planarization process may be performed on the insulating layer 300. Upon the procedure of FIG. 11, the fabrication of the electronic device 30 with the operable first transistor 700A and second transistor 700B has been completed. It should be appreciated that, similar to FIG. 6 described above, the electronic device 30 may also be combined with the piezoelectric unit 400 and the cavity 500 to constitute the piezoelectric micro-machined ultrasonic transducer (not shown for simplicity).

As stated above, in comparison with the second transistor, the first transistor has the higher operating voltage. Depending on the specific requirements, the gate insulating structure (the insulating structure between the semiconductor layer and the gate), the length of the lightly doped region in the semiconductor layer, and/or the concentration of the lightly doped region in the semiconductor layer may be adjusted. According to some embodiments (although not shown), the thickness of the first insulating structure in the first transistor may be designed to be larger than the thickness of the second insulating structure in the second transistor. The length of the lightly doped region in the first semiconductor layer of the first transistor and the length of the lightly doped region in the second semiconductor layer of the second transistor may be the same or different. The concentration of the lightly doped region in the first semiconductor layer of the first transistor and the concentration of the lightly doped region in the second semiconductor layer of the second transistor may be the same or different. The term “different” mentioned above may represent “larger than” or “smaller than”.

According to some embodiments (although not shown), the thickness of the first insulating structure in the first transistor and the thickness of the second insulating structure in the second transistor may be the same or different. The length of the lightly doped region in the first semiconductor layer of the first transistor may be designed to be larger than the length of the lightly doped region in the second semiconductor layer of the second transistor. The concentration of the lightly doped region in the first semiconductor layer of the first transistor and the concentration of the lightly doped region in the second semiconductor layer of the second transistor may be the same or different. According to some embodiments (although not shown), the thickness of the first insulating structure in the first transistor and the thickness of the second insulating structure in the second transistor may be the same or different. The length of the lightly doped region in the first semiconductor layer of the first transistor and the length of the lightly doped region in the second semiconductor layer of the second transistor may be the same or different. The concentration of the lightly doped region in the first semiconductor layer of the first transistor may be designed to be lower than the concentration of the lightly doped region in the second semiconductor layer of the second transistor.

The electronic device of the present disclosure allows the high-voltage element and the low-voltage element to be simultaneously configured onto the same substrate. According to some embodiments, the high-voltage element and the low-voltage element may be designed to sustain different voltages through adjusting the thicknesses of the insulating structures in the different elements. According to some embodiments, the high-voltage element and the low-voltage element may be designed to sustain different voltages through adjusting the lengths of the lightly doped regions in the different elements. According to some embodiments, the high-voltage element and the low-voltage element may be designed to sustain different voltages through adjusting the concentrations of the lightly doped regions in the different elements.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a substrate;
a first transistor disposed on the substrate and having a first operating voltage, wherein the first transistor comprises a first semiconductor layer, a first gate, and a first insulating structure disposed between the first semiconductor layer and the first gate; and
a second transistor disposed on the substrate and having a second operating voltage, wherein the second transistor comprises a second semiconductor layer, a second gate, and a second insulating structure disposed between the second semiconductor layer and the second gate,
wherein the first operating voltage is higher than the second operating voltage, and a thickness of the first insulating structure is greater than a thickness of the second insulating structure.

2. The electronic device of claim 1, wherein the first insulating structure comprises a first insulating layer, and a portion of the first insulating layer is disposed on sidewalls of the second gate.

3. The electronic device of claim 1, wherein the first operating voltage is between 30V and 100V, and the second operating voltage is between 5V and 30V.

4. The electronic device of claim 1, wherein a difference between the first operating voltage and the second operating voltage is between 5V and 95V.

5. The electronic device of claim 1, wherein the second insulating structure comprises a second insulating layer disposed between the substrate and the second gate, wherein the first insulating structure comprises the second insulating layer and a third insulating layer disposed between the second insulating layer and the first gate.

6. The electronic device of claim 5, wherein the second insulating layer and the third insulating layer comprise different materials in the first insulating structure.

7. The electronic device of claim 1, wherein the substrate comprises an active region and a peripheral region, and the first transistor and the second transistor are disposed in the active region and the peripheral region, respectively.

8. The electronic device of claim 7,
wherein the peripheral region comprises a gate circuit region, and the second transistor is disposed within the gate circuit region; and
a scan line disposed within the active region and electrically connected to the first transistor within the active region and the second transistor within the gate circuit region.

9. The electronic device of claim 1, further comprising:
a piezoelectric unit disposed on the first transistor.

10. An electronic device, comprising:
a substrate;
a first transistor disposed on the substrate and having a first operating voltage, wherein the first transistor comprises a first semiconductor layer, a first gate, and a first insulating structure disposed between the first semiconductor layer and the first gate, and the first semiconductor layer comprises a first channel region, a first lightly doped region, and a first heavily doped region; and
a second transistor disposed on the substrate and having a second operating voltage, wherein the second transistor comprises a second semiconductor layer, a second gate, and a second insulating structure disposed between the second semiconductor layer and the second gate, and the second semiconductor layer comprises a second channel region, a second lightly doped region, and a second heavily doped region,
wherein the first operating voltage is higher than the second operating voltage, and a length of the first lightly doped region is greater than a length of the second lightly doped region.

11. The electronic device of claim 10, wherein the first insulating structure comprises a first insulating layer, and a portion of the first insulating layer is disposed on sidewalls of the second gate.

12. The electronic device of claim 10, wherein the first operating voltage is between 30V and 100V, and the second operating voltage is between 5V and 30V.

13. The electronic device of claim 10, wherein a difference between the first operating voltage and the second operating voltage is between 5V and 95V.

14. The electronic device of claim 10, wherein the second insulating structure comprises a second insulating layer disposed between the substrate and the second gate, wherein the first insulating structure comprises the second insulating layer and a third insulating layer disposed between the second insulating layer and the first gate.

15. The electronic device of claim 14, wherein the second insulating layer and the third insulating layer comprise different materials in the first insulating structure.

16. The electronic device of claim 10, wherein a thickness of the first insulating structure is greater than a thickness of the second insulating structure.

17. The electronic device of claim 10, wherein the substrate comprises an active region and a peripheral region, and the first transistor and the second transistor are disposed in the active region and the peripheral region, respectively.

18. The electronic device of claim 10, wherein a concentration of the first lightly doped region is lower than a concentration of the second lightly doped region.

19. The electronic device of claim 10, wherein a concentration of the first heavily doped region is equal to a concentration of the second heavily doped region.

20. The electronic device of claim 10, wherein the first lightly doped region is disposed between the first channel region and the first heavily doped region, and the second lightly doped region is disposed between the second channel region and the second heavily doped region.
